(19) United States
(12) Patent Application Publication
(10) Pub. No.: US 2019/0027379 A1
(43) Pub. Date: Jan. 24, 2019

(54) SINTERED HEAT SPREADERS WITH INSERTS

(71) Applicant: Intel Corporation, Santa Clara, CA (US)

(72) Inventors: Wei Hu, Chandler, AZ (US); Aravindha R. Antoniswamy, Phoenix, AZ (US); Thomas J. Fitzgerald, Phoenix, AZ (US); Nikunj P. Patel, Cary, NC (US); Syadwad Jain, Chandler, AZ (US); Zhizhong Tang, Tempe, AZ (US); Shrenik Kothari, Phoenix, AZ (US)

(73) Assignee: Intel Corporation, Santa Clara, CA (US)

(21) Appl. No.: 15/767,126

(22) PCT Filed: Nov. 16, 2015
(86) PCT No.: PCT/US2015/060831

§ 371 Date: Apr. 9, 2018

(51) Int. Cl. H01L 21/48; H01L 23/367; H01L 23/373; H01L 23/544; H01L 23/42

(52) U.S. Cl. CPC H01L 21/4871; H01L 23/3675; H01L 23/3731; H01L 2223/54486; H01L 23/544; H01L 23/42; H01L 2223/54406; H01L 23/3736

(57) ABSTRACT

Disclosed herein are embodiments of sintered heat spreaders with inserts and related devices and methods. In some embodiments, a heat spreader may include: a frame including aluminum and a polymer binder; an insert disposed in the frame, wherein the insert has a thermal conductivity higher than a thermal conductivity of the frame; and a recess having at least one sidewall formed by the frame. The polymer binder may be left over from sintering frame material and insert material to form the heat spreader.

### TECHNICAL FIELD

The present disclosure relates generally to the field of thermal management and, more particularly, to sintered heat spreaders with inserts.

### BACKGROUND

Heat spreaders may be used to move heat away from an active electronic component so that it can be more readily dissipated by a heat sink or other thermal management device. Heat spreaders are conventionally stamped from copper and have a nickel coating.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a side cross-sectional view of an example heat spreader, in accordance with various embodiments.

FIGS. 2 and 3 are top and bottom perspective views, respectively, of the example heat spreader of FIG. 1, in accordance with various embodiments.

FIGS. 4-6 are side cross-sectional views of example arrangements of insert material, in accordance with various embodiments.

FIG. 7 is an exploded side cross-sectional view of an example heat spreader positioned above multiple integrated circuit (IC) packages in a computing device, in accordance with various embodiments.

FIG. 8 is a perspective view of the example heat spreader of FIG. 7, in accordance with various embodiments.

FIGS. 9, 10A, and 10B are side cross-sectional views of other example heat spreaders, in accordance with various embodiments.

FIGS. 11-14 illustrate various stages in the manufacture of an embodiment of the example heat spreader of FIG. 7, in accordance with various embodiments.

FIGS. 15-18 illustrate various stages in the manufacture of an embodiment of the example heat spreader of FIG. 9, in accordance with various embodiments.

FIGS. 19-25 illustrate various stages in the manufacture of an embodiment of the example heat spreader of FIG. 10, in accordance with various embodiments.

FIG. 26 is a side cross-sectional view of another example heat spreader, in accordance with various embodiments.

FIG. 27 is a flow diagram of a method of manufacturing a heat spreader, in accordance with various embodiments.

FIG. 28 is a block diagram of an example computing device that may include a heat spreader in accordance with the teachings of the present disclosure.

### DETAILED DESCRIPTION

Disclosed herein are embodiments of sintered heat spreaders with inserts and related devices and methods. In some embodiments, a heat spreader may include: a frame including aluminum and a polymer binder; an insert disposed in the frame, wherein the insert has a thermal conductivity higher than a thermal conductivity of the frame; and a recess having at least one sidewall formed by the frame. The polymer binder may be left over from sintering frame material and insert material to form the heat spreader.

Various ones of the embodiments disclosed herein may provide improved thermal management for complex computing device designs, such as those involving multiple integrated circuit (IC) packages of different heights and footprints distributed on a circuit board. Such complex computing device designs may arise in large computing server applications, “patch/package on interposer” configurations, and “package on package” configurations, among others. Additionally, various ones of the embodiments disclosed herein may be beneficially applied in computing tablets in which it may be advantageous to dissipate heat from computing components in the tablet both in the direction normal to the plane of the tablet and within the plane of the tablet. Various ones of the embodiments disclosed herein may include innovative material combinations, manufacturing techniques, and geometrical features.

Conventional techniques for forming heat spreaders typically involve stamping the heat spreader from a sheet of copper material. However, as IC packages grow and become more powerful, larger and thicker heat spreaders with more complex geometries may be desired. For example, it may be useful to have a heat spreader that is capable of moving heat from multiple silicon die of varying heights. However, the multi-hundred-ton presses required for stamping such heat spreaders are prohibitively large and expensive for practical use and may not even be capable of forming the desired geometries. Additionally, conventional stamping techniques are limited by the conventional practical maximum thickness of the copper sheet used during stamping. This copper sheet is typically provided on a roll and can only be wound so tightly before the copper begins to undesirably deform. Conventional techniques have been limited to copper sheets that are 3.2 mm thick or less, which limits the thickness of the heat spreader that can be formed from such sheets to 3.2 mm or less.

Additionally, the thermal management needs of a computing device may not require a heat spreader to be formed entirely from copper; for example, less heat may need to be dissipated at the edges of a large heat spreader than in the portions of the heat spreader closer to active dies. Because stamping a heat spreader from a copper sheet results in a heat spreader that is entirely formed from copper, and because copper is an expensive material, traditional stamping techniques may be both expensive and materially wasteful for some applications.

The use of stamping to form heat spreaders can also reduce the thermal and mechanical performance of a heat spreader, especially for complex geometries that require high-tonnage presses. In particular, the regions of the heat spreader that undergo very high deformation (such as the sidewalls of recesses in a heat spreader) are prone to recrystallize during surface mount reflow because of the stored plastic energy imparted to the material during stamping. Upon recrystallization, the strength of the heat spreader drops dramatically, and the heat spreader may warp or break.

Use of various ones of the embodiments disclosed herein may enable formation of heat spreaders with complex geometry at relatively low cost. This may allow powerful processing packages (e.g., central processing unit packages) with supporting memory chips to be cooled with a single large heat spreader. This may reduce cost overall and improve functionality, making new computing device designs (e.g., server designs) possible. Additionally, as cooler processors typically use less electricity and have improved reliability, use of various ones of the embodiments disclosed herein may provide an overall improvement in computing device performance. Various ones of the manufacturing operations using the manufacturing techniques disclosed herein (e.g., sintering) may be performed reliably, accurately, and at low cost, further enabling the development of improved heat spreader designs.

In the following detailed description, reference is made to the accompanying drawings that form a part hereof wherein like numerals designate like parts throughout, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. Although various elements may be provided with different reference numerals in one or more of the accompanying cross-sectional drawings, these elements may be coupled outside of the plane of the cross section, or they may be separate.

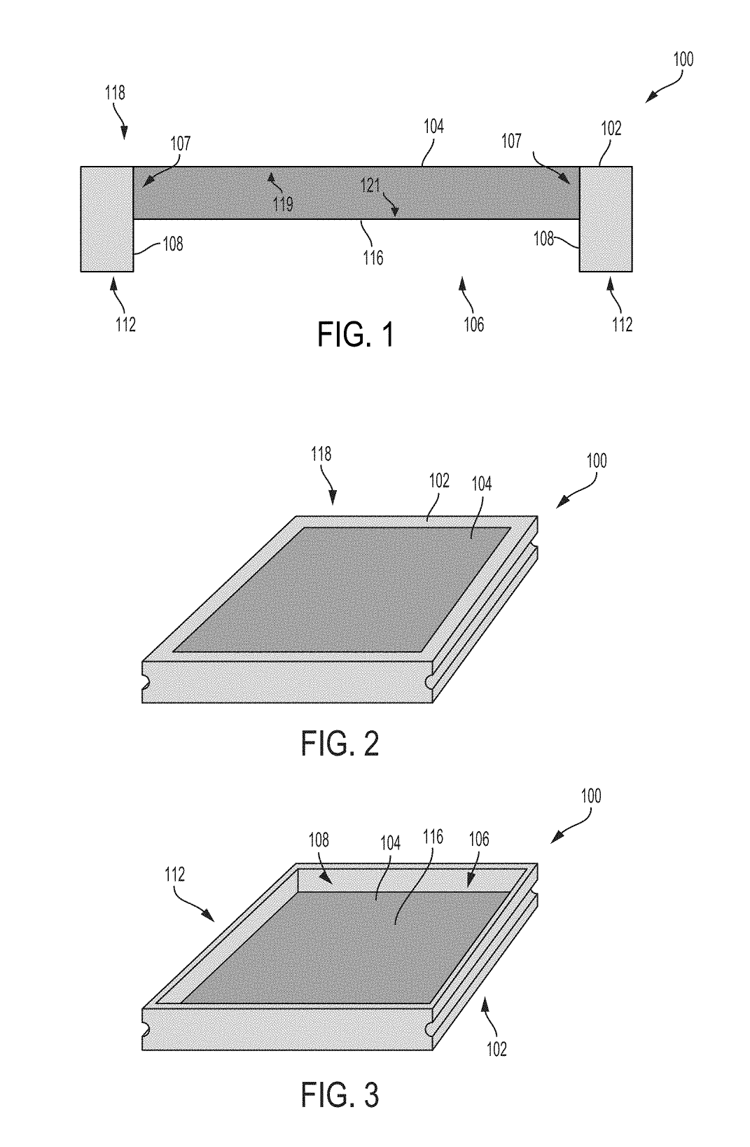

FIG. 1 is a side cross-sectional view of an example heat spreader 100, in accordance with various embodiments. The heat spreader 100 of FIG. 1 may include a frame 102. The frame may include aluminum (e.g., an aluminum alloy) and a polymer binder. Aluminum and its alloys may provide both adequate thermal conductivity and a low sintering temperature, and thus may be particularly useful in the frame 102 of the heat spreader 100. The polymer binder of the frame 102 may be residual binder left over from a sintering process used to form the heat spreader 100, as discussed in further detail below. In some embodiments, the polymer binder may include polyethylene glycol, poly(methyl methacrylate), stearic acid, or any other binder suitable for metal sintering.

An insert 104 may be disposed in the frame 102. The insert 104 may have a higher thermal conductivity than the frame 102, and thus the insert 104 may transfer heat more effectively than the frame 102. In some embodiments, a top outer surface 118 of the heat spreader 100 may be formed at least in part by the insert 104 (e.g., as shown in FIG. 1, in which the insert 104 and the frame 102 provide the top outer surface 118). In other embodiments, the insert 104 may be spaced away from the top outer surface 118 (e.g., by the frame 102).

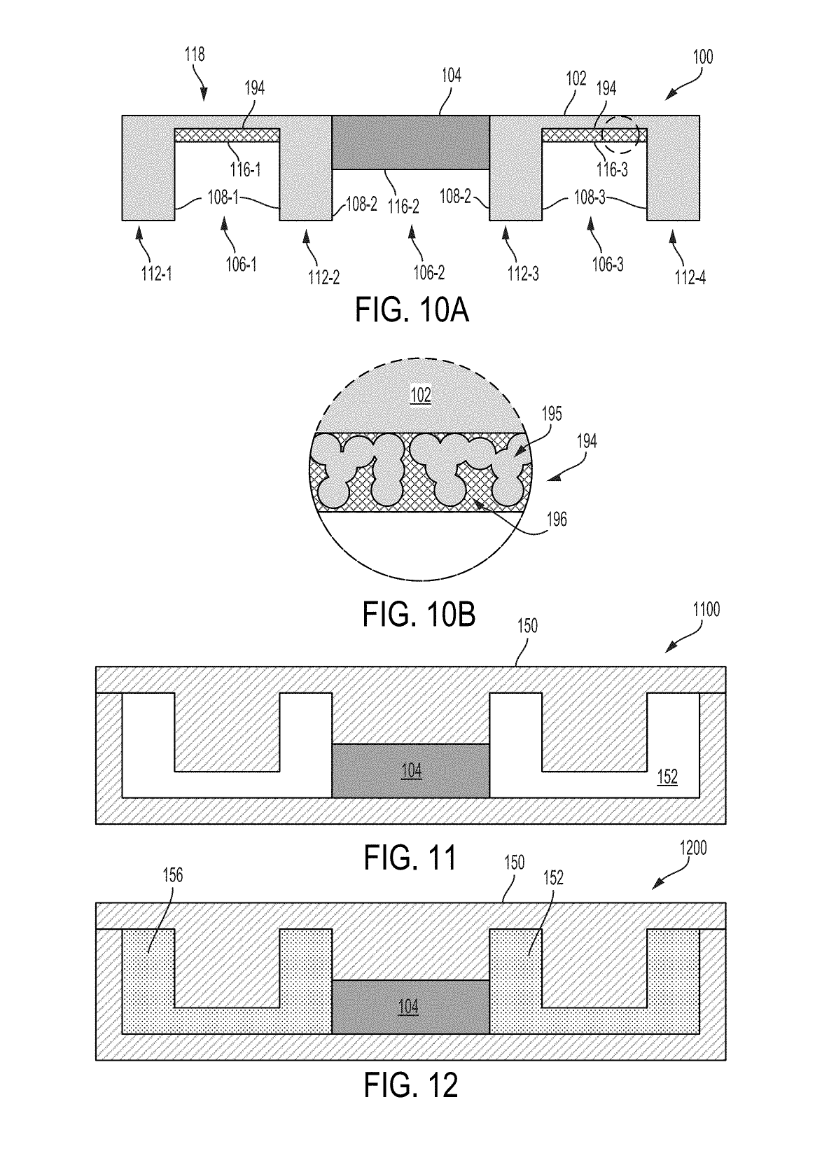

The heat spreader 100 may include a recess 106 having at least one sidewall 108 formed by the frame 102. In the embodiment shown in FIG. 1, the frame 102 may include a projection 112 that provides one or more of the sidewalls 108 of the recess 106. As illustrated in FIG. 3 (which provides a bottom perspective view of the example heat spreader 100 of FIG. 1), in some embodiments, the projection 112 may provide all four sidewalls 108 of the recess 106. In other embodiments (e.g., as discussed below with reference to FIG. 9), one or more of the sidewalls 108 of a recess 106 in a heat spreader 100 may be formed by the insert 104.

The recess 106 may have a recess bottom outer surface 116. As shown in the embodiment of FIG. 1, the recess bottom outer surface 116 may be formed by the insert 104. In other embodiments (e.g., as discussed below with reference to the recesses 106-1 and 106-3 of the heat spreader 100 of FIG. 7), a recess bottom outer surface 116 may be formed by the frame 102. In still other embodiments (e.g., as discussed below with reference to the recesses 106-1 and 106-3 of the heat spreader 100 of FIG. 26), a recess bottom outer surface 116 may be formed by the frame 102 and the insert 104.

In some embodiments, the heat spreader 100 may include a thermal interface material disposed at the recess bottom outer surface 116 of the recess 106 (not shown in FIG. 1). The thermal interface material may be applied to the recess bottom outer surface 116 just prior to bringing the heat spreader 100 into thermal contact with an IC package. In some embodiments, the thermal interface material may be disposed in pores of the frame 102 and/or the insert 104 as part of the manufacture of the heat spreader 100. Examples of such embodiments are discussed in further detail below with reference to FIGS. 10 and 25.

In some embodiments, the insert 104 may include boron nitride, a ceramic that has been conventionally used as an industrial abrasive. In particular, the insert 104 may be formed from a mixture of powdered boron nitride and powdered aluminum that, when sintered together, form a composite material having a thermal conductivity between the thermal conductivity of aluminum (approximately 225 W/m/K) and the thermal conductivity of boron nitride (approximately 740 W/m/K). Examples of manufacturing processes in which powdered boron nitride may be included in the insert 104 are discussed below with reference to FIGS. 9, 15-18 and 27).

In some embodiments, the insert 104 may include copper. For example, the insert 104 may include a copper preform (e.g., shaped substantially as a plate, as illustrated in the top and bottom perspective views of FIGS. 2 and 3, respectively). In embodiments in which the insert 104 includes copper, the copper may be high-grade oxygen free copper, or may be a lower-grade copper, such as electrolytic tough pitch copper or deoxidized high phosphorus copper (e.g., suitable in applications or regions of a particular heat spreader 100 in which the high thermal conductivity of oxygen free copper is not required). A copper preform included in the insert 104 may be entirely formed from copper or may be plated with another material, such as nickel. In some embodiments, it may be desirable to laser-mark a top outer surface 118 of the heat spreader 100 (e.g., to indicate a computing device product associated with the heat spreader 100). When laser marking is desired, the insert 104 and/or the entire heat spreader 100 may be plated with nickel or a noble metal (e.g., ruthenium, rhodium, palladium, silver, osmium, iridium, platinum, or gold) to facilitate the laser marking. Other materials that may be used in the insert 104 may be more difficult to laser-mark at the top outer surface 118 (such as copper, which may oxidize heavily).

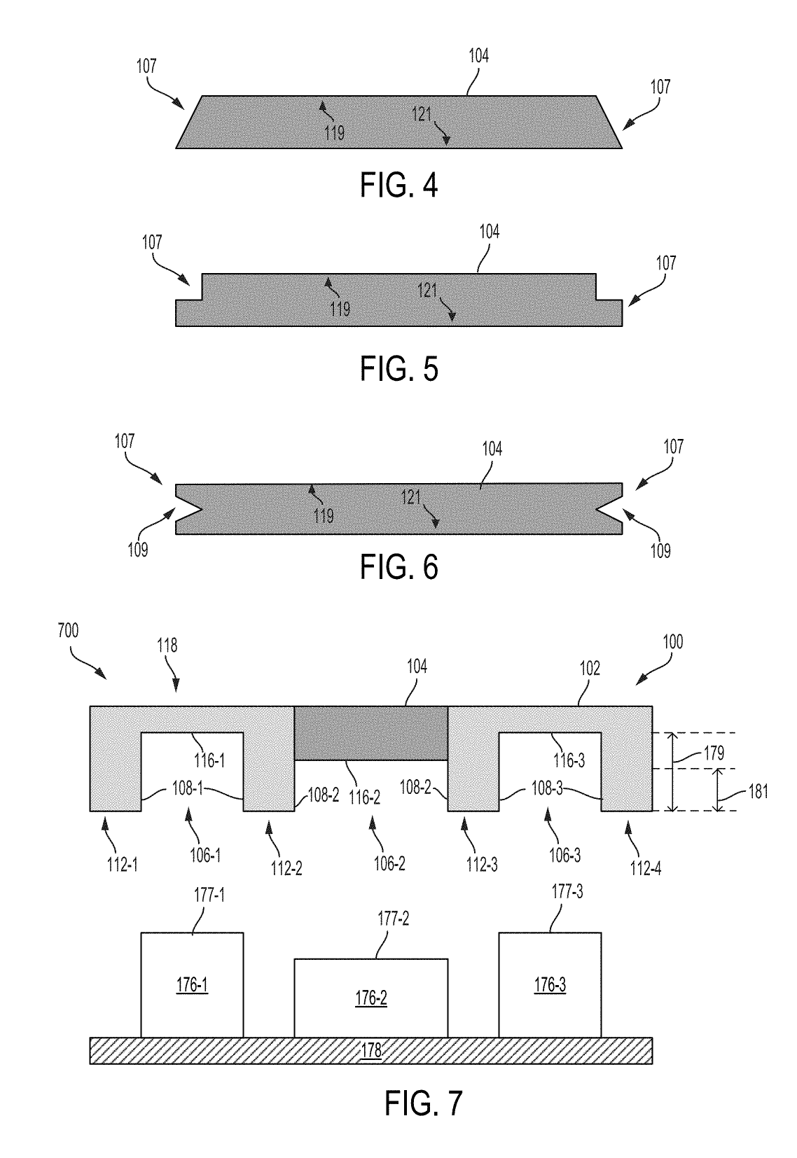

The insert 104 may have edges 107 in contact with the frame 102 (e.g., when the insert 104 includes a copper preform). FIG. 1 illustrates an embodiment in which these edges 107 may have substantially rectangular profiles, but this need not be the case; in other embodiments, the edges 107 of the insert 104 may have non-rectangular profiles. FIGS. 4-6 are side cross-sectional views of example arrangements of the insert 104, in accordance with various embodiments, showing different profiles for the edges 107. In particular, FIG. 4 illustrates an embodiment in which the edges 107 are angled with reference to a top surface 119 and a bottom surface 121 of the insert 104. FIG. 5 illustrates an embodiment in which the edges 107 have a stepped profile between the top surface 119 and the bottom surface 121 of the insert 104. Although a single “step” is illustrated in the profile of the edge 107 of FIG. 5, any number of steps may be included in a stepped profile. FIG. 6 illustrates an embodiment in which the edges 107 include a notch 109. Although a single notch having a particular shape is illustrated in FIG. 6, any number of notches having any one or more shapes may be included in a profile of an edge 107. The profiles illustrated in FIGS. 4-6 are simply illustrative and may be “flipped” with respect to the top surface 119 and the bottom surface 121, repeated in a single edge 107, or combined, as desired. More generally, any suitable profile may be used for the edges 107, such as a curved profile. A preform may be machined to have edges 107 having a desired profile using any suitable machining processes. For example, a preform may be stamped to form the angled or stepped profiles illustrated in FIGS. 4 and 5, respectively.

Returning to FIG. 1, in some embodiments, the selection of an appropriate material and form for the insert 104 may depend on the desired mechanical properties of the insert 104 and/or manufacturing considerations, among other factors. In some embodiments, it may be desirable for the frame 102 to be stronger and/or tougher than the insert 104. In such embodiments, the frame 102 may substantially provide mechanical robustness to the heat spreader 100 (while secondarily providing heat transfer capability) while the insert 104 may substantially provide heat transfer capability to the heat spreader 100 (while secondarily providing mechanical robustness). For example, the frame 102 may have a higher-yield strength than the insert 104. In another example, the frame 102 may have a higher toughness than the insert 104.

Depending upon the manufacturing constraints, it may be easier to use a preform as the insert 104 than to use a powdered insert material to form the insert 104. In particular, providing a preform into a sintering mold may be less expensive than pouring powdered material (e.g., powdered boron nitride) during the sintering process, and the preform can be sized and shaped as desired in advance with high precision. However, a powdered insert material may have its composition finely tuned (e.g., gradients and chemical composition) more readily than a preform.

As discussed above, the insert 104 and the frame 102 may be sintered together, forming a metallurgical bond that includes interdiffusion of the insert 104 and the frame 102. In some embodiments, the metallurgical bond formed by sintering may be supplemented by a mechanical interlocking that results from a non-rectangular profile of the edges 107 of the insert 104 in contact with the frame 102. In particular, the use of a non-rectangular profile for the edges 107 of the insert 104 may provide contact surfaces between the insert 104 and the frame 102 at multiple different angles and orientations. As the heat spreader 100 heats and cools (and the frame 102 and the insert 104 differentially expand and contract due to their different coefficients of thermal expansion), different ones of these multiple contact surfaces may resist separation between the frame 102 and the insert 104, improving the reliability of the heat spreader 100.

As noted above, FIGS. 2 and 3 are top and bottom perspective views, respectively, of the example heat spreader 100 of FIG. 1, in accordance with various embodiments. Although FIGS. 2 and 3 show the heat spreader 100 of FIG. 1 as having a substantially rectangular footprint, this need not be the case, and the heat spreader 100 of FIG. 1 (and any other heat spreaders disclosed herein) may have footprints of any desired shape. Additionally, the insert 104 and the frame 102 need not have footprints of the same shape. For example, the insert 104 may have a rectangular footprint with an aspect ratio that is different from an aspect ratio of a rectangular footprint of the frame 102. Examples of embodiments in which multiple inserts 104 are included in a frame 102 are discussed below with reference to FIG. 26. In another example, the insert 104 may have a curved footprint while the frame 102 may have a rectangular footprint.

As illustrated in FIGS. 1 and 2, the top outer surface 118 of the heat spreader 100 may be flat. Having the top outer surface 118 of the heat spreader 100 present a uniform material appearance, and a flat surface, may reduce the likelihood that test tools will scratch or get stuck on any non-uniformities during handling of the heat spreader 100. In some embodiments, the insert 104 may be exposed at the top outer surface 118 of the heat spreader 100 and at the recess bottom outer surface 116. In other embodiments, the insert 104 may not be exposed at any outer surface and may instead be enclosed by a coating material provided to the heat spreader 100. An example of such a coating material may include nickel, which may be electroplated on the heat spreader 100 to coat the entire outside of the heat spreader 100 in some embodiments (not shown in FIG. 1). As noted above, in some embodiments, the insert 104 may itself include a material coating (e.g., nickel) before it is disposed in the frame 102. When the insert 104 is formed of copper, providing a coating to the insert 104 to provide a barrier between the copper and the aluminum frame 102 may usefully prevent the formation of any electrochemical potential that may occur at a direct interface between copper and aluminum, but may not be required.

In the embodiment of the heat spreader 100 illustrated in FIG. 1, the insert 104 may have a substantially uniform “thickness” between the top surface 119 and the bottom surface 121, but this need not be the case. In some embodiments, the bottom surface 121 may include contours for various purposes (e.g., to match a contour of an integrated circuit (IC) package that will be in thermal contact with the bottom surface 121). Additionally, although the top surface 119 is shown as flat in the embodiments illustrated herein, the top surface 119 may also include contours if suitable for the application. For example, if another thermal management component will be disposed on the top outer surface 118 of the heat spreader 100 during use (e.g., a heat sink), the top surface 119 may include a recess or another feature complementary to that thermal management component. If the frame 102 entirely “covers” the insert 104 at the top outer surface 118, the frame 102 may include contours at the top outer surface 118, as discussed above, instead of or in addition to the insert 104.

In use, the heat spreader 100 of FIG. 1 may be arranged in a computing device such that one or more integrated circuit (IC) packages 176 (not shown in FIG. 1) are disposed in the recess 106 and in thermal contact with the recess bottom outer surface 116. The heat spreader 100 may be secured to a substrate to which the IC package 176 is secured (e.g., a circuit board) or may be secured directly to the IC package 176 (e.g., using a direct lid attach (DLA) process). Various examples of arrangements of heat spreaders 100 and IC packages 176 disposed within their recesses 106 are discussed below with reference to FIG. 7.

A heat spreader 100 may include multiple recesses 106. For example, FIG. 7 is an exploded side cross-sectional view of an example heat spreader 100 positioned above multiple IC packages 176 in a computing device 700. FIGS. 11-14, discussed below, illustrate various stages in the manufacture of the example heat spreader 100 of FIG. 7, in accordance with various embodiments.

The heat spreader 100 may include a frame 102 including aluminum and a polymer binder (as discussed above with reference to the heat spreader 100 of FIG. 1). The heat spreader 100 may include a recess 106-1 having a recess bottom outer surface 116-1 and sidewalls 108-1, a recess 106-2 (adjacent to the recess 106-1) having a recess bottom outer surface 116-2 and sidewalls 108-2, and a recess 106-3 (adjacent to the recess 106-2) having a recess bottom outer surface 116-3 and sidewalls 108-3. Projections 112-1 and 112-2 may define the sidewalls 108-1, projections 112-2 and 112-3 may define the sidewalls 108-2, and projections 112-3 and 112-4 may define the sidewalls 108-3, as shown.

In some embodiments of heat spreaders 100 having multiple recesses 106, the depths of different ones of the recesses 106 may be different. For example, in the heat spreader 100 of FIG. 7, the recess 106-2 may have a depth 181, while the recesses 106-1 and 106-3 may have a larger depth 179. In other embodiments of heat spreaders 100 having multiple recesses 106, the depths of different ones of the recesses 106 may be the same.

The heat spreader 100 may include an insert 104 disposed proximate to the recess 106-2. The insert 104 may be disposed in the frame 102 and may have a higher thermal conductivity than the frame 102, as discussed above. The insert 104 of the heat spreader 100 of FIG. 7 may take any of the forms discussed above with reference to the insert 104 of FIGS. 1-6, for example. As illustrated in FIG. 7, the insert 104 and the frame 102 may together provide the top outer surface 118 of the heat spreader 100. In some embodiments, the top outer surface 118 may be flat.

As noted above, FIG. 7 is an exploded side cross-sectional view of an example heat spreader 100 positioned above multiple IC packages 176 in a computing device 700. The IC packages 176 are shown in FIG. 7 as mounted to a circuit board 178; during use, the recess bottom outer surface 116-1 of the heat spreader 100 may be brought into contact with the top surface 177-1 of the IC package 176-1 such that the IC package 176-1 is disposed in the recess 106-1; the recess bottom outer surface 116-2 may be brought into contact with the top surface 177-2 of the IC package 176-2 such that the IC package 176-2 is disposed in the recess 106-2; and the recess bottom outer surface 116-3 may be brought into contact with the top surface 177-3 of the IC package 176-3 such that the IC package 176-3 is disposed in the recess 106-3. The heat spreader 100 may be secured to the IC packages 176 using an adhesive, for example. In some embodiments, the heat spreader 100 may be secured to the circuit board 178 (e.g., using an adhesive or a mechanical fastener) instead of or in addition to the top surfaces 177 of the IC packages 176.

The IC packages 176 may be in thermal contact with the recess bottom outer surfaces 116 of their respective recesses 106; this may include, for example, having the top surfaces 177 of the IC packages 176 in direct physical contact with the recess bottom outer surfaces 116 and/or having a thermally conductive material or materials directly in contact with the top surfaces 177 of the IC packages 176 and with the recess bottom outer surfaces 116. For example, a thermally conductive material may be disposed between the top surface 177 and the recess bottom outer surface 116. Examples of such a thermally conductive material may include a thermal interface material (e.g., a thermal interface material paste) or a thermally conductive epoxy (which may be a fluid when applied and may harden upon curing, as known in the art). The IC package 176-2 may be a higher-power device than the IC packages 176-1 and 176-3 and thus may benefit from the improved heat transfer capability of the insert 104 (relative to the frame 102).

In the embodiment of the heat spreader 100 illustrated in FIG. 7, the insert 104 forms the recess bottom outer surface 116-2 of a single recess 106-2 and “corresponds” to the IC package 176-2, as shown. This need not be the case. In some embodiments, a single insert 104 may “span” multiple IC packages 176, and/or multiple inserts 104 may “cover” a single IC package 176 (e.g., as discussed below with reference to the heat spreader 100 of FIG. 26). In some embodiments, multiple IC packages 176 may be disposed in a single recess 106.

In some embodiments of the heat spreaders 100 disclosed herein, the sidewalls 108 of a recess 106 may also be in thermal contact with one or more IC packages 176 disposed in the recess 106. In such embodiments, the recess 106 may “hug” an IC package 176 disposed therein and provide more surface contact for thermal transfer.

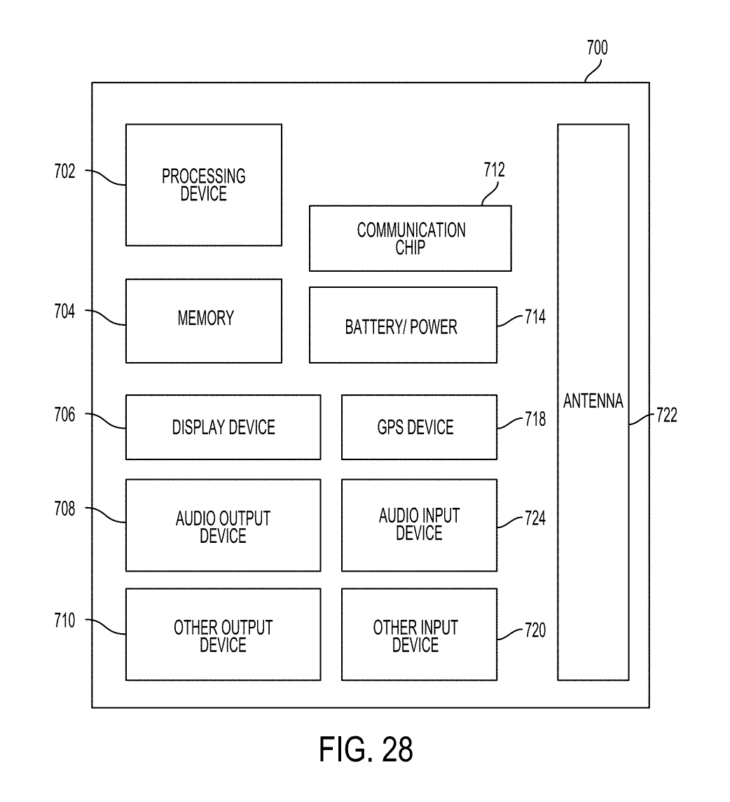

The IC packages 176 disposed in the recesses 106 of the heat spreaders 100 disclosed herein may include circuitry for performing any computing task. For example, an IC package 176 may include processing circuitry (e.g., a server processor, a digital signal processor, a central processing unit, a graphics processing unit, etc.), memory device circuitry, sensor circuitry, wireless or wired communication circuitry, or any other suitable circuitry. FIG. 28 (discussed below) illustrates an example of a computing device 700 that may include one or more of the heat spreaders 100 to thermally manage one or more of its components; any suitable ones of the components of the computing device 700 may be included in one or more IC packages 176 thermally managed by one or more heat spreaders 100.

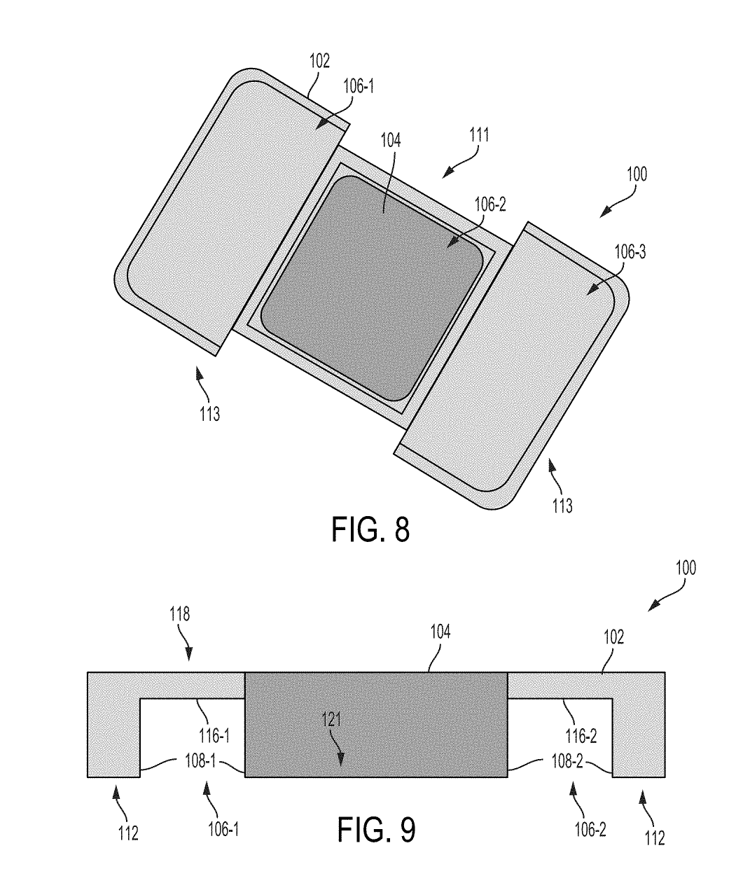

FIG. 8 is a perspective view of the example heat spreader 100 of FIG. 7, in accordance with various embodiments. As illustrated, the heat spreader 100 of FIG. 8 may include a central portion 111 and two wings 113. The central portion 111 may include the recess 106-2 having the insert 104 providing the recess bottom outer surface 116-2 (as shown in FIG. 7), while the wings 113 may include the recesses 106-1 and 106-3 (which have the frame 102 providing the recess bottom outer surfaces 116-1 and 116-3, respectively, as shown in FIG. 7). In use, the central portion 111 (having higher thermal conductivity) may be in thermal contact with the higher power IC package 176-2, while the wings 113 (having lower thermal conductivity) may be in thermal contact with the lower power IC packages 176-1 and 176-3.

FIG. 9 is a side cross-sectional view of another example heat spreader 100 having multiple recesses 106. FIGS. 15-18, discussed below, illustrate various stages in the manufacture of the example heat spreader 100 of FIG. 9, in accordance with various embodiments.

The heat spreader 100 may include a frame 102 including aluminum and a polymer binder (as discussed above with reference to the heat spreader 100 of FIG. 1). An insert 104 may be disposed in the frame 102. The insert 104 may have a higher thermal conductivity than the frame 102, as discussed above. The insert 104 of the heat spreader 100 of FIG. 9 may take any of the forms discussed above with reference to the insert 104 of FIGS. 1-6, for example. As illustrated in FIG. 9, the insert 104 and the frame 102 may together provide the top outer surface 118 of the heat spreader 100. In some embodiments, the top outer surface 118 may be flat.

The heat spreader 100 may include a recess 106-1 having a recess bottom outer surface 116-1 and sidewalls 108-1, and a recess 106-2 (adjacent to the recess 106-1) having a recess bottom outer surface 116-2 and sidewalls 108-2. The sidewalls 108-1 may be formed by a projection 112 of the frame 102 together with the insert 104, as shown; in other words, at least one of the sidewalls 108-1 may be provided by the projection 112 of the frame 102, and at least one sidewall 108-1 may be provided by the insert 104. Similarly, the sidewalls 108-1 may be formed by a projection 112 of the frame 102 together with the insert 104, as shown. Although the recesses 106-1 and 106-2 of the heat spreader 100 of FIG. 9 is shown as having a same depth, these recesses 106 may have different depths.

In use, the bottom surface 121 of the insert 104 may be brought into thermal contact with a top surface of an IC package (not shown), while other IC packages are brought into contact with the recess bottom outer surfaces 116 of the recesses 106 (not shown). As discussed above, thermal contact may include, for example, having the surfaces of the IC packages in direct physical contact with the heat spreader 100 and/or having a thermally conductive material or materials directly in contact with the surfaces of the IC packages and with the heat spreader 100.

In use, the heat spreader 100 of FIG. 9 may be arranged in a computing device such that one or more IC packages (not shown) are disposed in the recesses 106 and in thermal contact with the recess bottom outer surfaces 116. As noted above, one or more IC packages may be in thermal contact with the insert material 104 as well. The heat spreader 100 may be secured to a substrate to which the IC package is secured (e.g., a circuit board) or to the one or more IC packages themselves. The IC packages disposed in the recesses 106 of the heat spreaders 100 disclosed herein (including the heat spreader 100 of FIG. 9) may include circuitry for performing any computing task, such as any of the embodiments discussed herein with reference to FIGS. 7 and 28.

FIG. 10 illustrates another example heat spreader 100 having multiple recesses, in accordance with various embodiments. In particular, FIG. 10A is a side cross-sectional view of another example heat spreader 100 having multiple recesses 106, and FIG. 10B is a detailed view of the indicated portion of FIG. 10A. FIGS. 19-25, discussed below, illustrate various stages in the manufacture of the example heat spreader 100 of FIG. 9, in accordance various embodiments.

The heat spreader 100 of FIG. 10 may include a frame 102 including aluminum and a polymer binder (as discussed above with reference to the heat spreader 100 of FIG. 1). An insert 104 may be disposed in the frame 102. The insert 104 may have a higher thermal conductivity than the material of the frame 102, as discussed above. The insert 104 of the heat spreader 100 of FIG. 10 may take any of the forms discussed above with reference to the insert 104 of FIGS. 1-6, for example. As illustrated in FIG. 10A, the insert 104 and the frame 102 may together provide the top outer surface 118 of the heat spreader 100. In some embodiments, the top outer surface 118 may be flat.

The heat spreader 100 may include a recess 106-1 having a recess bottom outer surface 116-1 and sidewalls 108-1, and a recess 106-2 (adjacent to the recess 106-1) having a recess bottom outer surface 116-2 and sidewalls 108-2. The sidewalls 108-1 may be formed by projections 112-1 and 112-2 of the frame 102, the sidewalls 108-2 may be formed by projections 112-2 and 112-3 of the frame 102, and the sidewalls 108-3 may be formed by projections 112-3 and 112-4 of the frame 102. Although the recesses 106-1 and 106-3 of the heat spreader 100 of FIG. 10A are shown as having a depth that is different from a depth of the recess 106-2, these recesses 106 may have the same depths in other embodiments.

Thermal interface material (TIM) fill regions 194 may be disposed at the recess bottom outer surface 116-1 and the recess bottom outer surface 116-3. As illustrated in FIG. 10B, the TIM fill regions 194 may include a TIM 196 disposed in pores around sintered aluminum particles 195. In some embodiments, the TIM fill regions 194 may be formed by creating an area of higher aluminum porosity at the recess bottom outer surfaces 116 of recesses 106 formed in a frame 102, and pressing the TIM 196 into the open pores between the sintered aluminum particles 195. Interlocking between the TIM 196 and the aluminum particles 195 may help prevent delamination of the TIM 196 from the heat spreader 100 during use, addressing one of the most common failure mechanisms in many electronic packages. Additionally, the TIM 196 in the TIM fill regions 194 may act as a reservoir of TIM for the package bond line, providing TIM when needed (analogously to the reservoir of ink held by a felt pen). Examples of manufacturing techniques that may be used to form the TIM fill regions 194 are discussed below with reference to FIGS. 19-25.

In use, the heat spreader 100 of FIG. 10 may be arranged in a computing device such that one or more IC packages (not shown) are disposed in the recesses 106 and in thermal contact with the recess bottom outer surfaces 116. The heat spreader 100 may be secured to a substrate to which the IC package is secured (e.g., a circuit board) or to the one or more IC packages themselves. The IC packages disposed in the recesses 106 of the heat spreaders 100 disclosed herein (including the heat spreader 100 of FIG. 10) may include circuitry for performing any computing task, such as any of the embodiments discussed herein with reference to FIGS. 7 and 28.

Various ones of the embodiments disclosed herein may enable ultra-large and/or complex heat spreaders for server and other computing applications by injection molding sintering of aluminum (e.g., aluminum alloy) powders embedded with preforms (e.g., copper plates) or other insert materials. The aluminum frames 102 formed using the sintering techniques disclosed herein may be mechanically durable and dense, and may form strong metallurgical bonds with the inserts 104 (in addition to any mechanical interlocking that may arise from profiled insert edges 107). The inserts 104 may provide a highly conductive thermal path that may be particularly useful proximate to high-power central processing unit (CPU) dies or other high-power IC packages, while the aluminum frame 102 ensures adequate thermal conduction for other IC packages (e.g., low-power, non-CPU dies). Additionally, the sintering techniques disclosed herein provide flexibility in the design of the heat spreaders 100, enabling the formation of features not currently achievable using conventional stamping techniques.

The heat spreaders 100 disclosed herein may be formed using any suitable manufacturing techniques. For example, FIGS. 11-14 illustrate various stages in the manufacture of an embodiment of the heat spreader 100 of FIG. 7, in accordance with various embodiments. In particular, the manufacturing process illustrated by FIGS. 11-14 may be useful when the insert 104 includes a preform (e.g., a copper preform). While FIGS. 11-14 illustrate particular methods for manufacturing the heat spreader 100 of FIG. 7, any manufacturing techniques that can be used to form a heat spreader 100, in accordance with the present disclosure, may be used. For example, the heat spreader 100 of FIG. 9 may include an insert 104 that is formed from a powder instead of a preform (e.g., using others of the manufacturing techniques disclosed herein).

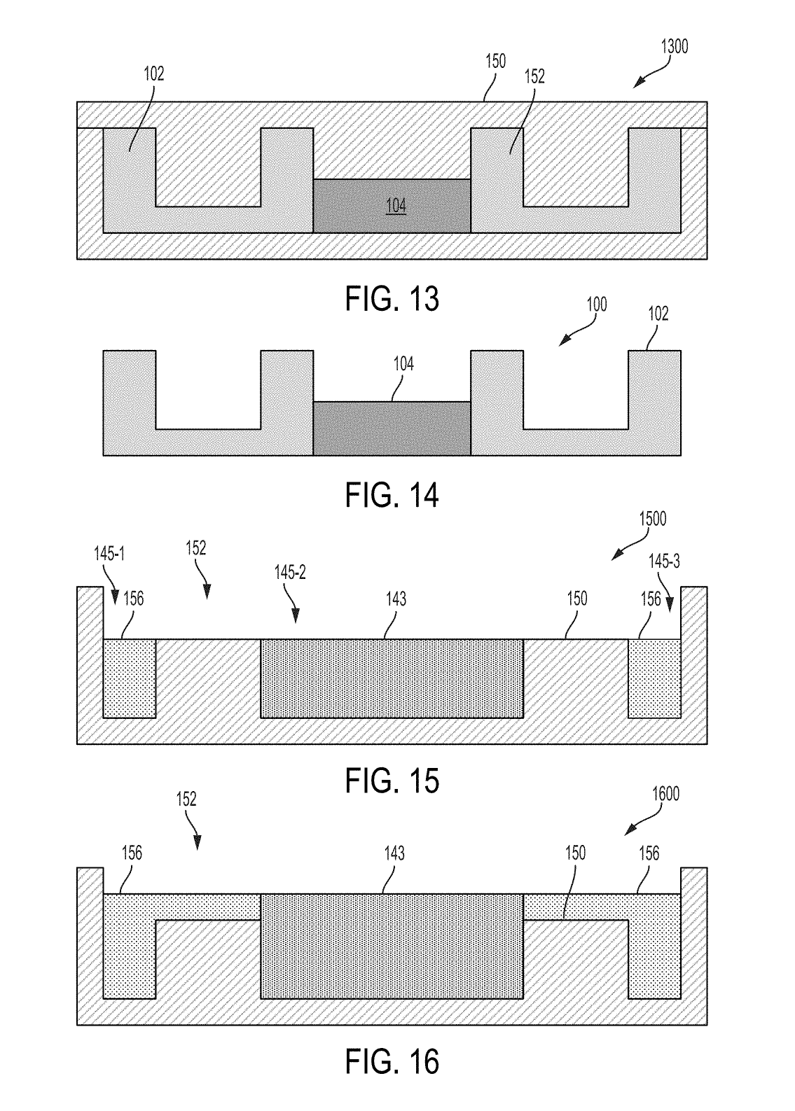

FIG. 11 depicts an assembly 1100 subsequent to providing a preform insert 104 in a cavity 152 of a mold 150. In embodiments in which the insert 104 is to be enclosed in the frame 102 and not exposed at the top outer surface 118 of the heat spreader 100, the insert 104 may be supported in the cavity 152 by solid pieces of the aluminum or aluminum alloy that will be used to make the frame 102. These pieces of material may be melted and/or otherwise absorbed into the frame 102 when the frame 102 is sintered (e.g., as discussed below with reference to FIG. 13), but may support the insert 104 and maintain the standoff between the insert 104 and the mold 150 until the bulk of the frame material is introduced into the cavity 152. In some embodiments, the insert 104 may be supported in the cavity 152 by solid pieces of a material different from the bulk of the frame material; these solid pieces of material may remain in the frame 102 after sintering. Any suitable ones of the preform inserts 104 disclosed herein may be provided in the cavity 152 in the assembly 1100 (e.g., any of the inserts 104 having various ones of the edge profiles discussed above with reference to FIGS. 1 and 4-6).

FIG. 12 depicts an assembly 1200 subsequent to providing frame material 156 to the cavity 152 of the assembly 1100. The frame material 156 may be provided via an inlet (not shown). The frame material 156 may include an aluminum powder (e.g., pure aluminum powder and/or an aluminum alloy powder). The frame material 156 may also include a polymer binder, such as any of the polymer binders discussed above with reference to FIG. 1. The amount and type of polymer binder included in the frame material 156 may depend on the rheological properties required by the particular injection flow process used, as well as the physical properties (e.g., density, thermal conductivity, dimension, etc.) of the sintered frame material 156, as known in the art of powder metallurgy. In some embodiments, the frame material 156 may include polymer binder in an amount that is less than 10% by weight. In some embodiments, the frame material 156 may include a polymer binder that has been previously heated to a melted state and mixed with the aluminum powder; the melted polymer binder and aluminum powder may be provided in the cavity 152 of the mold 150 while mixed.

FIG. 13 depicts an assembly 1300 subsequent to sintering the frame material 156 and the insert 104 of the assembly 1200 to form a heat spreader 100. In particular, the sintered frame material 156 may form the frame 102. As used herein, and is known in the art, “sintering” may refer to the welding together of materials by applying heat and/or pressure without melting the materials. The sintering temperature of aluminum may be approximately 400° C. In some embodiments, the sintering operations disclosed herein may be performed as part of a continuous sintering process in which a matrix of heat spreaders is simultaneously sintered and then singulated. Sintering may be particularly useful for forming components that are “thick” enough that an adequate volume of powder may be packed into a mold, but these components may have arbitrarily complex features. For the heat spreader applications disclosed herein, the manufacturing advantages of sintering may outweigh the typical high cost of the process in enabling the formation of high-performance heat spreaders.

Sintering the frame material 156 and the insert 104 may solidify the aluminum of the frame material 156 and form a strong metallurgical bond between the frame 102 and the insert 104 through interdiffusion between the components. The sintered bond between the frame 102 and the insert 104 may also facilitate lateral thermal conduction by reducing contact resistance relative to purely mechanical joining, and thus the sintered heat spreaders 100 disclosed herein may provide improved thermal performance over conventionally mechanically joined heat spreaders. Although the bulk of the polymer binder may be burnt out of the assembly 1300 during sintering, some residual polymer binder is likely to remain in the frame 102 as a signature of the sintering process. As discussed above, the insert 104 may be selected so as to have a higher thermal conductivity than the frame 102.

FIG. 14 depicts a heat spreader 100 subsequent to removing the heat spreader 100 from the assembly 1300 (“demolding” the heat spreader 100). The heat spreader 100 of FIG. 14 may have substantially the form of the heat spreader 100 of FIG. 7, discussed above, but may be further shaped before it takes its final form (e.g., as discussed below). As shown in FIG. 14, the heat spreader 100 may include a frame 102 formed by sintering the frame material 156. The insert 104 may be disposed in the frame 102, and may have a higher thermal conductivity than the frame 102.

Further processing operations may be performed on the heat spreader 100 of FIG. 14, such as polishing the top outer surface 118 (e.g., with a high-speed drill bit) and/or the recess bottom outer surface 116, laser-marking the heat spreader 100 (e.g., on the top outer surface 118 with indicia of the computing device 700 in which the heat spreader 100 will be included), removing an inlet projection resulting from any residual frame material and an inlet of the mold 150, applying any desired coatings to the heat spreader 100 (e.g., nickel-plating the heat spreader 100), or any other desired processing operations.

FIGS. 15-18 illustrate various stages in the manufacture of an embodiment of the heat spreader 100 of FIG. 9, in accordance with various embodiments. In particular, the manufacturing process illustrated by FIGS. 15-18 may be useful when the insert 104 is formed from a powder. While FIGS. 15-18 illustrate particular methods for manufacturing the heat spreader 100 of FIG. 9, any manufacturing techniques that can be used to form a heat spreader 100, in accordance with the present disclosure, may be used. For example, the heat spreader 100 of FIG. 9 may be formed with an insert 104 that includes a preform instead of or in addition to a powder (e.g., using others of the manufacturing techniques disclosed herein).

FIG. 15 depicts an assembly 1500 subsequent to providing a frame material 156 in recesses 145-1 and 145-3 in a cavity 152 of a mold 150, and subsequent to providing an insert material 143 in a recess 145-2 in the cavity 152. The frame material 156 may include an aluminum powder (e.g., pure aluminum powder and/or an aluminum alloy powder). The frame material 156 may also include a polymer binder, such as any of the polymer binders discussed above with reference to FIG. 1. In some embodiments, as discussed above with reference to FIG. 12, the frame material 156 may include a polymer binder that has been previously heated to a melted state and mixed with the aluminum powder; the melted polymer binder and aluminum powder may be provided in the recesses 145-1 and 145-3 of the cavity 152 of the mold 150 while mixed. The insert material 143 may include a powdered material, such as boron nitride powder (as discussed above with reference to FIG. 1). In some embodiments, the insert material 143 may also include aluminum powder and a polymer binder. The ratios of aluminum powder and boron nitride in the insert material 143 may depend on the desired thermal conductivity of the insert material 143, as discussed above. Cost constraints may also be relevant; if the insert material 143 (having a higher thermal conductivity) is expensive, it may be selectively provided to the cavity 152 so that the insert 104 formed by the sintered insert material 143 is positioned in a location that is most important for heat transfer (e.g., above a high-power CPU).

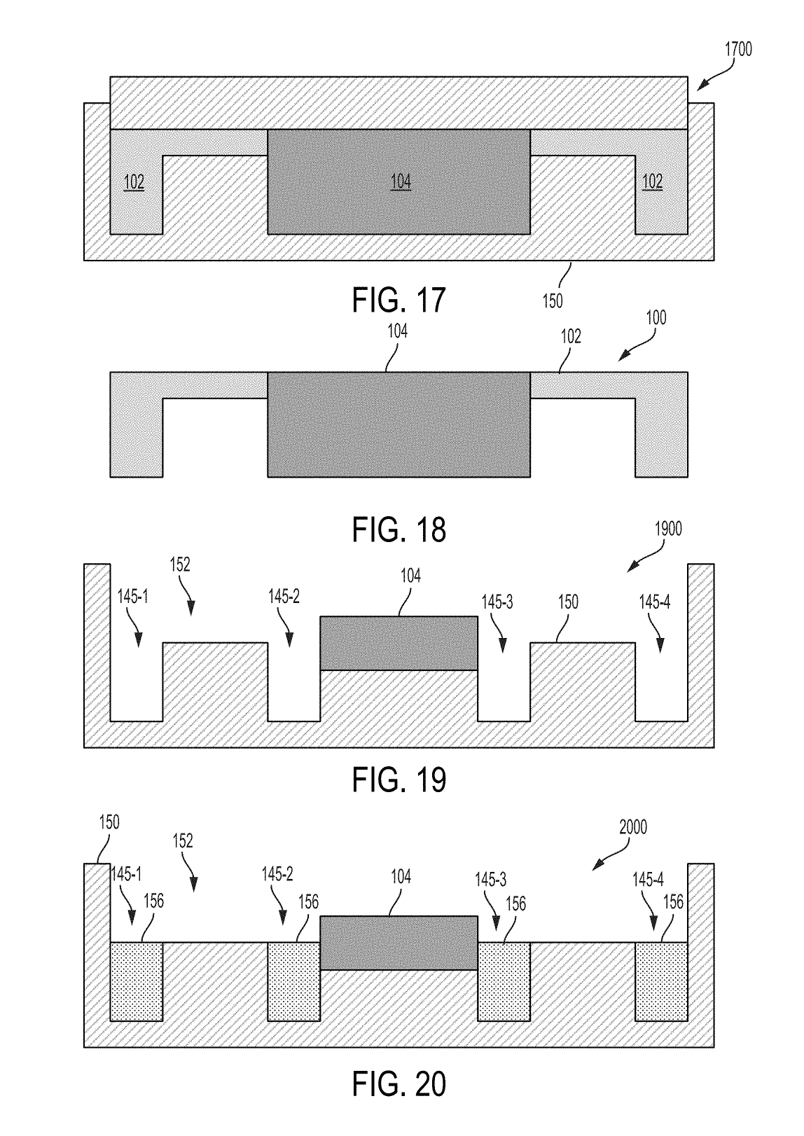

FIG. 16 depicts an assembly 1600 subsequent to providing additional frame material 156 and additional insert material 143 in the cavity 152 of the assembly 1500. When the frame material 156 and the insert material 143 are in powdered form, or are thick enough when they include a melted polymer binder, the frame material 156 and the insert material 143 may be selectively disposed in the cavity 152 so that they remain in desired locations within the cavity 152 prior to sintering (discussed below with reference to FIG. 17). In particular, the frame material 156 and the insert material 143 may be provided to the cavity 152 in layers, as desired.

FIG. 17 depicts an assembly 1700 subsequent to closing the mold 150 and sintering the frame material 156 and the insert material 143 of the assembly 1600 to form a heat spreader 100. In particular, the sintered frame material 156 may form the frame 102, and the sintered insert material 143 may form the insert 104. As discussed above with reference to FIG. 13, sintering the frame material 156 and the insert material 143 may solidify the aluminum of the frame material 156 and form a strong metallurgical bond between the frame 102 and the insert 104 through interdiffusion between the components. Although the bulk of the polymer binder may be burnt out of the assembly 1700 during sintering, some residual polymer binder is likely to remain in the frame 102 as a signature of the sintering process. As discussed above, the insert 104 may be selected so as to have a higher thermal conductivity than the frame 102.

FIG. 18 depicts a heat spreader 100 subsequent to removing the heat spreader 100 from the assembly 1700 (“demolding” the heat spreader 100). The heat spreader 100 of FIG. 18 may have substantially the form of the heat spreader 100 of FIG. 9, discussed above, but may be further shaped before it takes its final form (e.g., as discussed below). As shown in FIG. 18, the heat spreader 100 may include a frame 102, formed by sintering the frame material 156, and an insert 104, formed by sintering the insert material 143. The insert 104 may be disposed in the frame 102 and may have a higher thermal conductivity than the frame 102. Any of the further processing operations discussed above with reference to FIG. 14 may be performed on the heat spreader 100 of FIG. 18.

FIGS. 19-25 illustrate various stages in the manufacture of an embodiment of the heat spreader 100 of FIG. 10, in accordance with various embodiments. In particular, the manufacturing process illustrated by FIGS. 19-25 may be useful when the insert 104 includes a preform. While FIGS. 19-25 illustrate particular methods for manufacturing the heat spreader 100 of FIG. 10, any manufacturing techniques that can be used to form a heat spreader 100, in accordance with the present disclosure, may be used. For example, the heat spreader 100 of FIG. 10 may include an insert 104 that is formed from a powder instead of or in addition to a preform (e.g., using others of the manufacturing techniques disclosed herein).

FIG. 19 depicts an assembly 1900 subsequent to providing a preform insert 104 in a cavity 152 of a mold 150. As discussed above with reference to FIG. 11, in embodiments in which the insert 104 is to be enclosed in the frame 102 and not exposed at a recess bottom outer surface 116 of the heat spreader 100, the insert 104 may be supported in the cavity 152 by solid pieces of the aluminum or aluminum alloy that will be used to make the frame 102, and/or by solid pieces of a material different from the bulk of the frame material; these solid pieces of material may remain in the frame 102 after sintering. Any suitable ones of the preform inserts 104 disclosed herein may be provided in the cavity 152 in the assembly 1900 (e.g., any of the inserts 104 having various ones of the edge profiles discussed above with reference to FIGS. 1 and 4-6). The mold 150 may include recesses 145-1, 145-2, 145-3 and 145-4.

FIG. 20 depicts an assembly 2000 subsequent to providing a frame material 156 in the cavity 152 of the assembly 1900 and, in particular, in the recesses 145-1, 145-2, 145-3, and 145-4 of the mold 150. As discussed above with reference to FIG. 15, the frame material 156 may include an aluminum powder (e.g., pure aluminum powder and/or an aluminum alloy powder). The frame material 156 may also include a polymer binder, such as any of the polymer binders discussed above with reference to FIG. 1. In some embodiments, as discussed above with reference to FIG. 12, the frame material 156 may include a polymer binder that has been previously heated to a melted state and mixed with the aluminum powder; the melted polymer binder and aluminum powder may be provided in the recesses 145 of the cavity 152 of the mold 150 while mixed.

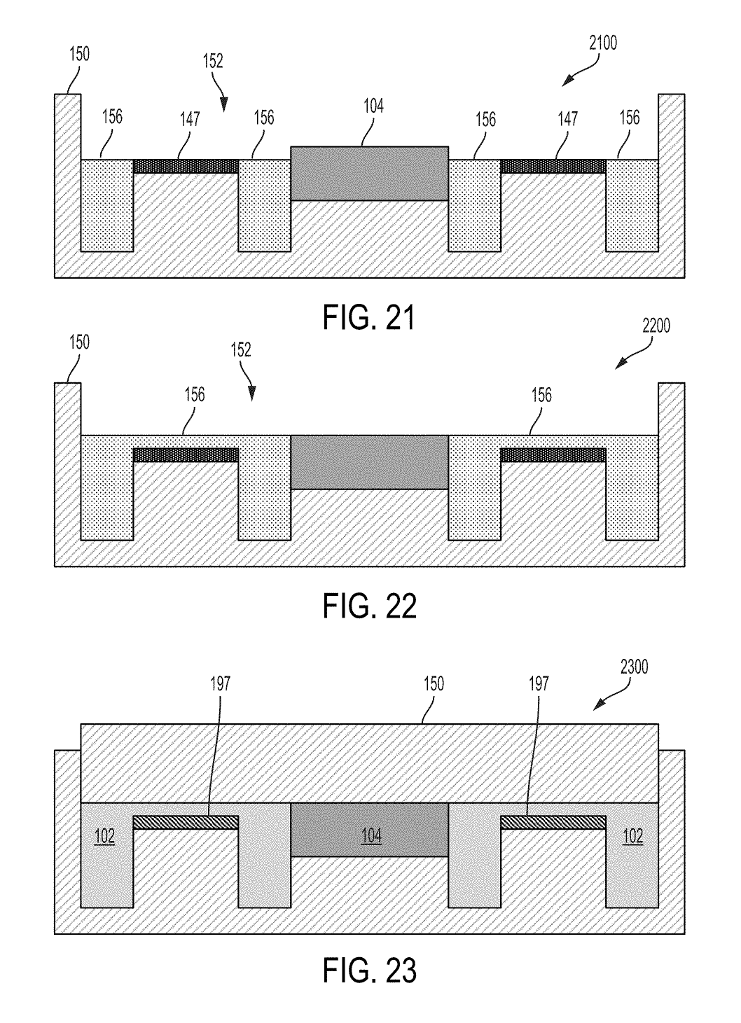

FIG. 21 depicts an assembly 2100 subsequent to providing additional frame material 156 and TIM fill region material 147 in the cavity 152 of the assembly 2000. The TIM fill region material 147 may also include aluminum powder and a polymer binder (as included in the frame material 156) but may include a higher percentage of polymer binder in the frame material 156. When the frame material 156 and the TIM fill region material 147 are in powdered form, or are thick enough when they include a melted polymer binder, the frame material 156 and the TIM fill region material 147 may be selectively disposed in the cavity 152 so that they remain in desired locations within the cavity 152 prior to sintering (discussed below with reference to FIG. 23).

FIG. 22 depicts an assembly 2200 subsequent to providing additional frame material 156 in the cavity 152 of the assembly 2100. As shown in FIG. 22, this additional frame material 156 may “cover” the TIM fill region material 147.

FIG. 23 depicts an assembly 2300 subsequent to closing the mold 150 and sintering the frame material 156, the TIM fill region material 147, and the insert 104 of the assembly 2200. The sintered TIM fill region material 147 may form porous regions 197. Since the percentage of polymer binder in the TIM fill region material 147 was larger than the percentage of polymer binder in the frame material 156, upon burning out of the polymer binder during sintering, the porosity of the porous regions 197 (e.g., the open space between metal particles) may be greater than the porosity of the sintered frame material 156.

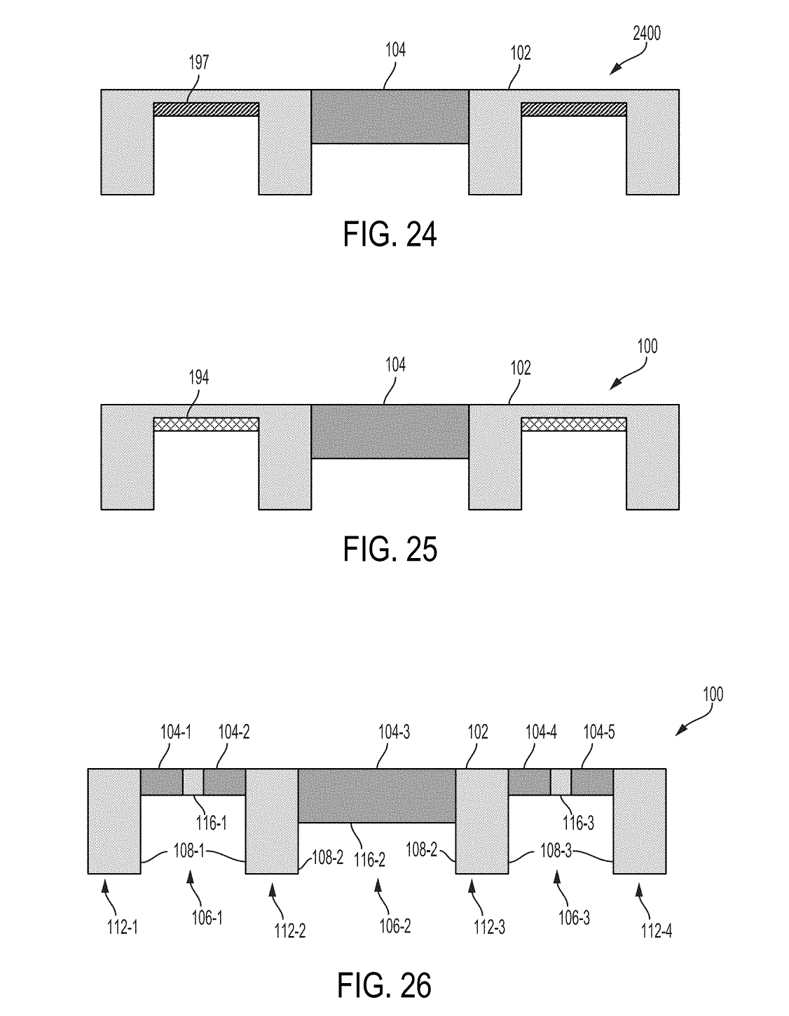

FIG. 24 depicts an assembly 2400 subsequent to removing the heat spreader 100 from the assembly 2300 (“demolding” the heat spreader 100). Any of the further processing operations discussed above with reference to FIG. 14 may be performed on the heat spreader 100 of FIG. 24.

FIG. 25 depicts a heat spreader 100 subsequent to backfilling the porous regions 197 of the assembly 2400 with a TIM to form the heat spreader 100 of FIG. 10, including the TIM fill regions 194. In particular, the sintered frame material 156 and the TIM fill regions 194 may form the frame 102. As discussed above with reference to FIG. 13, sintering the frame material 156 and the insert 104 may solidify the aluminum of the frame material 156 and form a strong metallurgical bond between the frame 102 and the insert 104 through interdiffusion between the components. Although the bulk of the polymer binder may be burnt out of the assembly 2400 during sintering (FIG. 23), some residual polymer binder is likely to remain in the frame 102 as a signature of the sintering process. As discussed above, the insert 104 may be selected so as to have a higher thermal conductivity than the frame 102.

As discussed above (e.g., with reference to FIG. 7), a heat spreader 100 may include multiple recesses 106. A heat spreader 100 may alternately or additionally include multiple inserts 104. For example, FIG. 26 is a side cross-sectional view of an example heat spreader 100 including multiple inserts 104. The heat spreader 100 of FIG. 26 may include a frame 102 including aluminum and a polymer binder (as discussed above with reference to the heat spreader 100 of FIG. 1). The heat spreader 100 may include a recess 106-1 having a recess bottom outer surface 116-1 and sidewalls 108-1, a recess 106-2 (adjacent to the recess 106-1) having a recess bottom outer surface 116-2 and sidewalls 108-2, and a recess 106-3 (adjacent to the recess 106-2) having a recess bottom outer surface 116-3 and sidewalls 108-3. Projections 112-1 and 112-2 may define the sidewalls 108-1, projections 112-2 and 112-3 may define the sidewalls 108-2, and projections 112-3 and 112-4 may define the sidewalls 108-3, as shown. As noted above, the depths of different ones of the recesses 106 may be different, or may be the same. In use, one or more IC packages may be disposed in each of the recesses 106.

The heat spreader 100 may include inserts 104-1 and 104-2 disposed proximate to the recess 106-1 and, in particular, proximate to the recess bottom outer surface 116-1. The heat spreader 100 may include an insert 104-3 disposed proximate to the recess 106-2 and, in particular, proximate to the recess bottom outer surface 116-2. The heat spreader 100 may include inserts 104-4 and 104-5 disposed proximate to the recess 106-3 and, in particular, proximate to the recess bottom outer surface 116-3. The inserts 104 may be disposed in the frame 102, and may each have a higher thermal conductivity than the frame 102. The inserts 104 of the heat spreader 100 of FIG. 26 may take any of the forms discussed herein (e.g., formed from powder or preforms, having non-rectangular edge profiles, etc.). As illustrated in FIG. 7, the inserts 104 and the frame 102 may together provide the top outer surface 118 of the heat spreader 100. In some embodiments, the top outer surface 118 may be flat.

In use, the heat spreader 100 may be brought into thermal contact with the top surfaces of one or more IC packages (not shown). As discussed above, thermal contact may include, for example, having the surfaces of the IC packages in direct physical contact with the heat spreader 100 and/or having a thermally conductive material or materials directly in contact with the surfaces of the IC packages and with the heat spreader 100. In use, the heat spreader 100 of FIG. 26 may be arranged in a computing device such that one or more IC packages (not shown) are disposed in the recesses 106 and in thermal contact with the recess bottom outer surfaces 116. The heat spreader 100 may be secured to a substrate to which the IC package is secured (e.g., a circuit board) or to the one or more IC packages themselves. The IC packages disposed in the recesses 106 of the heat spreaders 100 disclosed herein (including the heat spreader 100 of FIG. 26) may include circuitry for performing any computing task, such as any of the embodiments discussed herein with reference to FIGS. 7 and 28.

Any of the embodiments and features of the heat spreaders 100 discussed herein may be combined in any suitable manner in the design of a heat spreader in accordance with the present disclosure. For example, any of the following features may be combined as desired: different profiles of the edges 107 of the insert 104 (e.g., discussed above with reference to FIGS. 1 and 4-6), compositions of the insert 104, single- or multi-recess geometries for the heat spreader 100, the use of a thermal interface material in pores at a recess bottom outer surface 116, and manufacturing techniques.

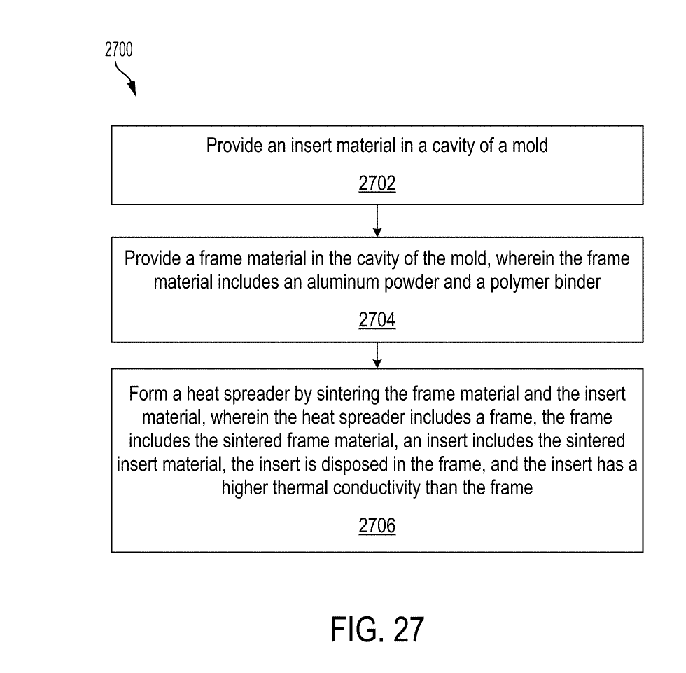

FIG. 27 is a flow diagram of a method 2700 of manufacturing a heat spreader, in accordance with various embodiments. While the operations of the method 2700 are arranged in a particular order in FIG. 27 and illustrated once each, in various embodiments, one or more of the operations may be repeated (e.g., when the heat spreader includes multiple inserts 104).

At 2702, an insert material may be provided in a cavity of a mold. For example, as discussed above with reference to FIG. 11, a preform insert 104 may be provided in a cavity 152 of a mold 150. In another example, as discussed above with reference to FIG. 15, an insert material 143 may be provided in a recess 145-2 in a cavity 152 of a mold 150. When the insert material provided at 2702 includes a preform, edges of the preform may be profiled with a rectangular or a non-rectangular profile (e.g., as discussed above with reference to FIGS. 4-6) prior to providing the preform in the cavity of the mold.

At 2704, a frame material may be provided in the cavity of the mold. The frame material may include an aluminum powder and a polymer binder. For example, as discussed above with reference to FIG. 12, a frame material 156 may be provided in a cavity 152 of a mold 150. In another example, as discussed above with reference to FIG. 15, a frame material 156 may be provided in recesses 145-1 and 145-3 in a cavity 152 of a mold 150.

At 2706, a heat spreader may be formed by sintering the frame material (2704) and the insert material (2702). The heat spreader may include a frame, the frame may include the sintered frame material, the insert may include the sintered insert material, the insert may be disposed in the frame, and the insert may have a higher thermal conductivity than the frame. For example, as discussed above with reference to FIG. 13, a heat spreader 100 may be formed by sintering the frame material 156 into a frame 102, the insert 104 of the heat spreader 100 may include the sintered preform insert 104, the insert 104 may be disposed in the frame 102, and the insert 104 may have a higher thermal conductivity than the frame 102. In another example, as discussed above with reference to FIG. 17, a heat spreader 100 may be formed by sintering the frame material 156 into a frame 102, the insert 104 of the heat spreader 100 may include the sintered insert material 143, the insert 104 may be disposed in the frame 102, and the insert 104 may have a higher thermal conductivity than the frame 102.

In some embodiments, further operations may follow 2706, such as nickel-plating the heat spreader, polishing a surface of the heat spreader, and/or laser-marking a surface of the heat spreader. In some embodiments, a portion of the heat spreader, proximate to a recess bottom outer surface, may be backfilled with a thermal interface material, as discussed above with reference to FIGS. 10 and 19-25.

FIG. 28 is a block diagram of an example computing device 700 that may include any of the embodiments of the heat spreader 100 disclosed herein. A number of components are illustrated in FIG. 28 as included in the computing device 700, but any one or more of these components may be omitted or duplicated, as suitable for the application.

Additionally, in various embodiments, the computing device 700 may not include one or more of the components illustrated in FIG. 28, but the computing device 700 may include interface circuitry for coupling to the one or more components. For example, the computing device 700 may not include a display device 706, but may include display device interface circuitry (e.g., a connector and driver circuitry) to which a display device 706 may be coupled. In another set of examples, the computing device 700 may not include an audio input device 724 or an audio output device 708, but may include audio input or output device interface circuitry (e.g., connectors and supporting circuitry) to which an audio input device 724 or audio output device 708 may be coupled. Any one or more of the components of the computing device 700 may be included in one or more IC packages that may be in thermal contact with any of the heat spreaders 100 disclosed herein.

The computing device 700 may include a processing device 702 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 702 may include one or more digital signal processors (DSPs), application-specific integrated circuits (ASICs), central processing units (CPUs), graphics processing units (GPUs), cryptoprocessors, server processors, or any other suitable processing devices. The computing device 700 may include a memory 704, which may itself include one or more memory devices such as volatile memory (e.g., dynamic random access memory (DRAM)), non-volatile memory (e.g., read-only memory (ROM)), flash memory, solid state memory, and/or a hard drive.

In some embodiments, the computing device 700 may include a communication chip 712 (e.g., one or more communication chips). For example, the communication chip 712 may be configured for managing wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not.

The communication chip 712 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 712 may operate in accordance with a Global System for Mobile communication (GSM), General Packet Radio Service (GPRS), Universal Mobile Telecommunications System (UMTS), High Speed Packet Access (HSPA), Evolved HSPA (E-HSPA), or LTE network. The communication chip 712 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 712 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 712 may operate in accordance with other wireless protocols in other embodiments. The computing device 700 may include an antenna 722 to facilitate wireless communications and/or to receive other wireless communications (such as AM or FM radio transmissions).

In some embodiments, the communication chip 712 may manage wired communications, such as electrical, optical, or any other suitable communication protocols (e.g., the Ethernet). As noted above, the communication chip 712 may include multiple communication chips. For instance, a first communication chip 712 may be dedicated to shorter-range wireless communications such as Wi-Fi or Bluetooth, and a second communication chip 712 may be dedicated to longer-range wireless communications such as GPS, EDGE, GPRS, CDMA, WiMAX, LTE, EV-DO, or others. In some embodiments, a first communication chip 712 may be dedicated to wireless communications, and a second communication chip 712 may be dedicated to wired communications.

The computing device 700 may include battery/power circuitry 714. The battery/power circuitry 714 may include one or more energy storage devices (e.g., batteries or capacitors) and/or circuitry for coupling components of the computing device 700 to an energy source separate from the computing device 700 (e.g., AC line power).

The computing device 700 may include a display device 706 (or corresponding interface circuitry, as discussed above). The display device 706 may include any visual indicators, such as a heads-up display, a computer monitor, a projector, a touchscreen display, a liquid crystal display (LCD), a light-emitting diode display, or a flat panel display, for example.

The computing device 700 may include an audio output device 708 (or corresponding interface circuitry, as discussed above). The audio output device 708 may include any device that generates an audible indicator, such as speakers, headsets, or earbuds, for example.

The computing device 700 may include an audio input device 724 (or corresponding interface circuitry, as discussed above). The audio input device 724 may include any device that generates a signal representative of a sound, such as microphones, microphone arrays, or digital instruments (e.g., instruments having a musical instrument digital interface (MIDI) output).

The computing device 700 may include a global positioning system (GPS) device 718 (or corresponding interface circuitry, as discussed above). The GPS device 718 may be in communication with a satellite-based system and may receive a location of the computing device 700, as known in the art.

The computing device 700 may include another output device 710 (or corresponding interface circuitry, as discussed above). Examples of the other output device 710 may include an audio codec, a video codec, a printer, a wired or wireless transmitter for providing information to other devices, or an additional storage device.

The computing device 700 may include another input device 720 (or corresponding interface circuitry, as discussed above). Examples of the other input device 720 may include an accelerometer, a gyroscope, an image capture device, a keyboard, a cursor control device such as a mouse, a stylus, a touchpad, a bar code reader, a Quick Response (QR) code reader, any sensor, or a radio frequency identification (RFID) reader.

The following paragraphs describe examples of various ones of the embodiments disclosed herein.

Example 1 is a heat spreader, including: a frame including aluminum and a polymer binder; an insert disposed in the frame, wherein the insert has a thermal conductivity higher than a thermal conductivity of the frame; and a recess having at least one sidewall formed by the frame.

Example 2 may include the subject matter of Example 1, and may further specify that the insert includes a copper preform.

Example 3 may include the subject matter of Example 2, and may further specify that the copper preform is plated with nickel.

Example 4 may include the subject matter of any of Examples 2-3, and may further specify that the copper preform has edges in contact with the frame, and the edges have non-rectangular profiles.

Example 5 may include the subject matter of Example 4, and may further specify that the edges have a stepped profile.

Example 6 may include the subject matter of any of Examples 1-5, and may further specify that the recess has a recess bottom outer surface formed by the insert.

Example 7 may include the subject matter of any of Examples 1-6, and may further specify that the heat spreader has a top outer surface formed in part by the insert.

Example 8 may include the subject matter of Example 1, and may further specify that the insert includes boron nitride.

Example 9 may include the subject matter of Example 8, and may further specify that the insert includes aluminum.

Example 10 may include the subject matter of any of Examples 1-9, and may further specify that the polymer binder includes polyethylene glycol, poly(methyl methacrylate), or stearic acid.

Example 11 may include the subject matter of any of Examples 1-10, and may further include a thermal interface material disposed in pores of the frame at a recess bottom outer surface of the recess.

Example 12 may include the subject matter of any of Examples 1-11, and may further specify that the recess is a first recess, and the heat spreader further includes a second recess having at least one sidewall formed by the frame.

Example 13 may include the subject matter of Example 12, and may further specify that the frame provides a recess bottom outer surface of the second recess.

Example 14 may include the subject matter of Example 12, and may further specify that the insert is a first insert, and the heat spreader further includes a second insert disposed in the frame, wherein a recess bottom outer surface of the first recess is proximate to the first insert and a recess bottom outer surface of the second recess is proximate to the second insert.

Example 15 may include the subject matter of Example 14, and may further specify that the first insert has a same material composition as the second insert.

Example 16 may include the subject matter of Example 12, and may further specify that a depth of the first recess is different from a depth of the second recess.

Example 17 may include the subject matter of any of Examples 1-16, and may further specify that the frame and the insert are interdiffused.

Example 18 is a method of manufacturing a heat spreader, including: providing an insert material in a cavity of a mold; providing a frame material in the cavity of the mold, the frame material including an aluminum powder and a polymer binder; and forming a heat spreader by sintering the frame material and the insert material, wherein the heat spreader includes a frame, the frame includes the sintered frame material, an insert includes the sintered insert material, the insert is disposed in the frame, and the insert has a higher thermal conductivity than the frame.

Example 19 may include the subject matter of Example 18, and may further specify that the cavity is shaped to provide a recess to the heat spreader, and the recess has at least one sidewall formed by the frame.

Example 20 may include the subject matter of Example 19, and may further specify that the recess has a recess bottom outer surface, and providing the frame material in the cavity of the mold comprises providing polymer binder in a greater concentration in a portion of the cavity corresponding to the recess bottom outer surface than in other portions of the cavity.

Example 21 may include the subject matter of Example 20, and may further include: after forming the heat spreader, removing the heat spreader from the mold; and backfilling the portion of the heat spreader proximate to the recess bottom outer surface with a thermal interface material.

Example 22 may include the subject matter of Example 18, and may further specify that the insert material includes a copper preform.

Example 23 may include the subject matter of Example 22, and may further specify that the copper preform has an edge with a non-rectangular profile.

Example 24 may include the subject matter of Example 22, and may further include, prior to providing the insert material in the cavity of the mold, stamping the copper preform to provide an edge of the copper preform with a non-rectangular profile.

Example 25 may include the subject matter of Example 18, and may further specify that the insert material includes boron nitride powder.

Example 26 may include the subject matter of Example 25, and may further specify that the insert material includes the aluminum powder and the polymer binder.

Example 27 may include the subject matter of Example 18, and may further specify that the aluminum powder and the polymer binder are mixed together prior to provision in the cavity of the mold and are provided in the cavity of the mold while mixed.

Example 28 may include the subject matter of Example 18, and may further specify that the polymer binder is in a melted state when the frame material is provided in the cavity of the mold.

Example 29 is a computing device, including: a heat spreader, including a frame including aluminum and a polymer binder, an insert disposed in the frame, wherein the insert has a thermal conductivity higher than a thermal conductivity of the frame, and a recess having at least one sidewall formed by the frame; and an integrated circuit (IC) package disposed in the recess.

Example 30 may include the subject matter of Example 29, and may further include a thermal interface material disposed between a surface of the IC package and a surface of the heat spreader.

Example 31 may include the subject matter of any of Examples 29-30, and may further specify that: the recess is a first recess; the heat spreader further comprises a second recess having at least one sidewall formed by the frame, wherein the second recess is adjacent to the first recess; the IC package is a first IC package; and the computing device further comprises a second IC package disposed in the second recess.

Example 32 may include the subject matter of Example 31, and may further specify that a recess bottom outer surface of the second recess is formed by the frame.

Example 33 may include the subject matter of any of Examples 29-32, and may further specify that the IC package includes a server processor.

1. A heat spreader, comprising:
a frame including aluminum and a polymer binder;
an insert disposed in the frame, wherein the insert has a thermal conductivity higher than a thermal conductivity of the frame; and
a recess having at least one sidewall formed by the frame.

2. The heat spreader of claim 1, wherein the insert includes a copper preform.

3. The heat spreader of claim 2, wherein the copper preform is plated with nickel.

4. The heat spreader of claim 2, wherein the copper preform has edges in contact with the frame, and the edges have non-rectangular profiles.

5. The heat spreader of claim 1 wherein the heat spreader has a top outer surface formed in part by the insert.

6. The heat spreader of claim 1, wherein the insert includes boron nitride.

7. The heat spreader of claim 6, wherein the insert includes aluminum.

8. The heat spreader of claim 1, further comprising:
a thermal interface material disposed in pores of the frame at a recess bottom outer surface of the recess.

9. The heat spreader of claim 1, wherein the recess is a first recess, and the heat spreader further comprises:
a second recess having at least one sidewall formed by the frame.

10. The heat spreader of claim 9, wherein the frame provides a recess bottom outer surface of the second recess.

11. The heat spreader of claim 9, wherein the insert is a first insert, and the heat spreader further comprises a second insert disposed in the frame, wherein a recess bottom outer surface of the first recess is proximate to the first insert and a recess bottom outer surface of the second recess is proximate to the second insert.

12. The heat spreader of claim 11, wherein the first insert has a same material composition as the second insert.

13. The heat spreader of claim 9, wherein a depth of the first recess is different from a depth of the second recess.

14. A method of manufacturing a heat spreader, comprising:
providing an insert material in a cavity of a mold;
providing a frame material in the cavity of the mold, the frame material including an aluminum powder and a polymer binder; and
forming a heat spreader by sintering the frame material and the insert material, wherein the heat spreader includes a frame, the frame includes the sintered frame material, an insert includes the sintered insert material, the insert is disposed in the frame, and the insert has a higher thermal conductivity than the frame.

15. The method of claim 14, wherein the cavity is shaped to provide a recess to the heat spreader, and the recess has at least one sidewall formed by the frame.

16. The method of claim 15, wherein the recess has a recess bottom outer surface, and providing the frame material in the cavity of the mold comprises providing polymer binder in a greater concentration in a portion of the cavity corresponding to the recess bottom outer surface than in other portions of the cavity.

17. The method of claim 16, further comprising:
after forming the heat spreader, removing the heat spreader from the mold; and
backfilling a portion of the heat spreader proximate to the recess bottom outer surface with a thermal interface material.

18. The method of claim 14, wherein the insert material includes a copper preform.

19. The method of claim 18, wherein the copper preform has an edge with a non-rectangular profile.

20. The method of claim 14, wherein the insert material includes boron nitride powder.

21. The method of claim 14, wherein the aluminum powder and the polymer binder are mixed together prior to provision in the cavity of the mold and are provided in the cavity of the mold while mixed.

22. A computing device, comprising:
a heat spreader, including:
a frame including aluminum and a polymer binder,
an insert disposed in the frame, wherein the insert has a thermal conductivity higher than a thermal conductivity of the frame, and
a recess having at least one sidewall formed by the frame; and
an integrated circuit (IC) package disposed in the recess.

23. The computing device of claim 22, wherein:
the recess is a first recess;
the heat spreader further comprises a second recess having at least one sidewall formed by the frame, wherein the second recess is adjacent to the first recess;
the IC package is a first IC package; and
the computing device further comprises a second IC package disposed in the second recess.

24. The computing device of claim 23, wherein a recess bottom outer surface of the second recess is formed by the frame.

25. The computing device of claim 22 wherein the IC package includes a server processor.
